(19) United States
(12) Patent Application Publication
(10) Pub. No.: US 2023/0034503 A1
(43) Pub. Date: Feb. 2, 2023

(54) COMPOSITION FOR CHEMICAL MECHANICAL POLISHING, CHEMICAL MECHANICAL POLISHING METHOD, AND METHOD FOR MANUFACTURING PARTICLES FOR CHEMICAL MECHANICAL POLISHING

(71) Applicant: JSR CORPORATION, Tokyo (JP)

(72) Inventors: Pengyu Wang, Tokyo (JP); Kouji Nakanishi, Tokyo (JP); Tatsuya Yamanaka, Tokyo (JP)

(73) Assignee: JSR CORPORATION, Tokyo (JP)

(21) Appl. No.: 17/781,376

(22) PCT Filed: Nov. 18, 2020
(86) PCT No.: PCT/JP2020/042918

§ 371 Date: Jun. 1, 2022

(30) Foreign Application Priority Data
Dec. 20, 2019 (JP) 2019-230145

(51) Int. Cl. C09G 1/02

(52) U.S. Cl. CPC C09G 1/02

(57) ABSTRACT

Provided are a composition for chemical mechanical polishing and a chemical mechanical polishing method, which enable reduction in occurrence of surface defects in a polished surface and which enable high speed polishing of a tungsten film which is a wiring material. The composition for chemical mechanical polishing contains: (A) particles containing alumina and having a functional group represented by general formula (1); and (B) a liquid medium. (1): —SO₃⁻M⁺ (In the formula, M⁺ represents a monovalent cation.)

### TECHNICAL FIELD

The present invention relates to a composition for chemical mechanical polishing and a chemical mechanical polishing method using the same, and a method for manufacturing particles for chemical mechanical polishing.

### BACKGROUND ART

Chemical mechanical polishing (CMP) has rapidly become widespread in flattening techniques and the like in manufacture of semiconductor devices. This CMP is a technique in which an object to be polished is press-bonded to a polishing pad, the object to be polished and the polishing pad are made to slide against each other while a composition for chemical mechanical polishing is supplied to the polishing pad, and the object to be polished is chemically and mechanically polished.

In recent years, as semiconductor devices have become finer, wiring layers composed of wirings, plugs and the like formed in semiconductor devices have become finer. Along with this, a method of flattening a wiring layer by chemical mechanical polishing is used. A wiring substrate in a semiconductor device contains an insulating film material, a wiring material, and a barrier metal material for preventing the wiring material from diffusing into an inorganic material film. Silicon dioxide is mainly used as the insulating film material, copper and tungsten are mainly used as the wiring material, and tantalum nitride and titanium nitride are mainly used as the barrier metal material.

Alumina particles having high hardness may be used in order to polish such various materials at a high speed. Specifically, a polishing composition containing alumina, fumed alumina, acid, and water has been proposed (for example, refer to Patent Literature 1).

### CITATION LIST

### Patent Literature

Patent Literature 1: Japanese Patent Laid-Open No. 2004-331886

### SUMMARY OF INVENTION

### Technical Problem

However, in the polishing composition described in Patent Literature 1, when alumina particles having high hardness are used, a tungsten film can be polished at a high speed, but there is a problem of polishing scratches such as scratches being likely to occur on the polished surface on which a tungsten film and a silicon oxide film coexist. Such polishing scratches are a main factor that lowers the yield.

Accordingly, there is a demand for a composition for chemical mechanical polishing and a chemical mechanical polishing method through which it is possible to polish a tungsten film which is a wiring material at a high speed and reduce the occurrence of surface defects on a polished surface.

### Solution to Problem

One aspect of a composition for chemical mechanical polishing according to the present invention includes

(A) particles having a functional group represented by the following General Formula (1) and containing alumina; and

(B) a liquid medium:

—SO₃⁻M⁺ (1)

(M⁺ represents a monovalent cation).

In one aspect of the composition for chemical mechanical polishing, the component (A) may be particles having a surface to which the functional group represented by General Formula (1) is fixed via a covalent bond and containing alumina.

In any of the above aspects of the composition for chemical mechanical polishing, at least a portion of the surface of the particles may be coated with a silica coating, and in the coating, if the number of moles of the functional group represented by General Formula (1) is M_{Sul}, and the number of moles of silicon is M_{Si}, the value of M_{Sul}/M_{Si} may be 0.001 or more and 0.2 or less.

In any of the above aspects of the composition for chemical mechanical polishing, the film thickness of the silica coating may be 1 nm or more and 10 nm or less.

In any of the above aspects of the composition for chemical mechanical polishing, the average primary particle size of the particles may be 50 nm or more and 300 nm or less.

In any of the above aspects of the composition for chemical mechanical polishing, a zeta potential of the component (A) measured using a laser Doppler method may be lower than −10 mV.

In any of the above aspects of the composition for chemical mechanical polishing, the pH may be 1 or more and 6 or less.

The composition for chemical mechanical polishing according to any of the above aspects may be for polishing a substrate containing tungsten.

One aspect of a chemical mechanical polishing method according to the present invention includes a process in which a substrate containing tungsten is polished using the composition for chemical mechanical polishing according to any one of the above aspects.

In one aspect of the chemical mechanical polishing method, the substrate may further contain silicon oxide.

In any of the above aspects of the chemical mechanical polishing method, the pH of the composition for chemical mechanical polishing may be 1 or more and 6 or less.

One aspect of a method for manufacturing particles for chemical mechanical polishing according to the present invention includes,

a process (a) in which alumina particles are dispersed in water to prepare an alumina particle aqueous dispersing liquid having a solid content concentration of 1 mass % or more and 30 mass % or less,
a process (b) in which a total amount of 1 part by mass or more and 50 parts by mass or less of a tetrafunctional alkoxysilane compound and a silanol compound having a functional group represented by the following General Formula (1) with respect to a total amount of 100 parts by mass of the alumina particles is added to the alumina particle aqueous dispersing liquid, and
a process (c) in which a silica coating is grown on the surface of the alumina particles:

—SO₃⁻M⁺ (1)

(M⁺ represents a monovalent cation).

In one aspect of the method for manufacturing particles for chemical mechanical polishing, the process (c) may be performed at a temperature of 90° C. or lower.

In any of the above aspects of the method for manufacturing particles for chemical mechanical polishing, the process (a) may further include adding ammonia water to the alumina particle aqueous dispersing liquid.

### Advantageous Effects of Invention

According to the composition for chemical mechanical polishing of the present invention, in chemical mechanical polishing performed when a wiring of a semiconductor device is formed, it is possible to polish a tungsten film which is a wiring material at a high speed and reduce the occurrence of surface defects on the polished surface. In particular, when the polished surface is a polished surface on which a tungsten film and a silicon oxide film coexist, it is possible to effectively reduce the occurrence of polishing scratches such as scratches.

### BRIEF DESCRIPTION OF DRAWINGS

FIG. 1 is a cross-sectional view schematically showing a particle containing alumina used in the present embodiment.

FIG. 2 is a cross-sectional view schematically showing a workpiece used in a chemical mechanical polishing method according to the present embodiment.

FIG. 3 is a cross-sectional view schematically showing a workpiece after a first polishing process.

FIG. 4 is a cross-sectional view schematically showing a workpiece after a second polishing process.

FIG. 5 is a perspective view schematically showing a chemical mechanical polishing device.

### DESCRIPTION OF EMBODIMENTS

Preferable embodiments of the present invention will be described below in detail. Here, the present invention is not limited to the following embodiments, and includes various modified examples implemented in ranges without changing the spirit of the present invention.

In this specification, “(meth)acrylic-” is a concept including both “acrylic-” and “methacrylic-”.

In this specification, the “wiring material” refers to a conductor metal material such as aluminum, copper, cobalt, titanium, ruthenium, and tungsten. The “insulating film material” refers to a material such as silicon dioxide, silicon nitride, or amorphous silicon. “Barrier metal material” refers to a material that is used by being laminated with a wiring material in order to improve reliability of a wiring of tantalum nitride, titanium nitride or the like.

In this specification, a numerical range described as “X to Y” is interpreted as a range including the numerical value X as a lower limit value and the numerical value Y as an upper limit value.

### 1. Composition for Chemical Mechanical Polishing

A composition for chemical mechanical polishing according to one embodiment of the present invention contains (A) particles having a functional group represented by the following General Formula (1) and containing alumina (in this specification, simply referred to as a “component (A)”) and (B) a liquid medium (in this specification, simply referred to as a “component (B)”).

—SO₃⁻M⁺ (1)

(M⁺ represents a monovalent cation).

Hereinafter, respective components contained in the composition for chemical mechanical polishing according to the present embodiment will be described in detail.

### 1.1. Component (A)

### 1.1.1. Structure and Physical Properties

A composition for chemical mechanical polishing according to the present embodiment contains, as particles for chemical mechanical polishing, (A) particles having a functional group represented by the following General Formula (1) and containing alumina.

—SO₃⁻M⁺ (1)

(M⁺ represents a monovalent cation).

Examples of monovalent cations represented by M⁺include H⁺, Li⁺, Na⁺, K⁺, and NH₄⁺, but the present invention is not limited thereto. That is, in other words, the component (A) may be “(A) particles having at least one functional group selected from the group consisting of a sulfo group and salts thereof and containing alumina.” Here, “a salt of a sulfo group” is a functional group in which a hydrogen ion contained in a sulfo group (—SO₃H) is replaced with a monovalent cation such as Li⁺, Na⁺, K⁺, or NH4⁺. The component (A) is particles having a surface to which the functional group represented by General Formula (1) is fixed via a covalent bond and containing alumina, and does not include a component having a surface to which a compound having the functional group represented by General Formula (1) is physically or ionically adsorbed.

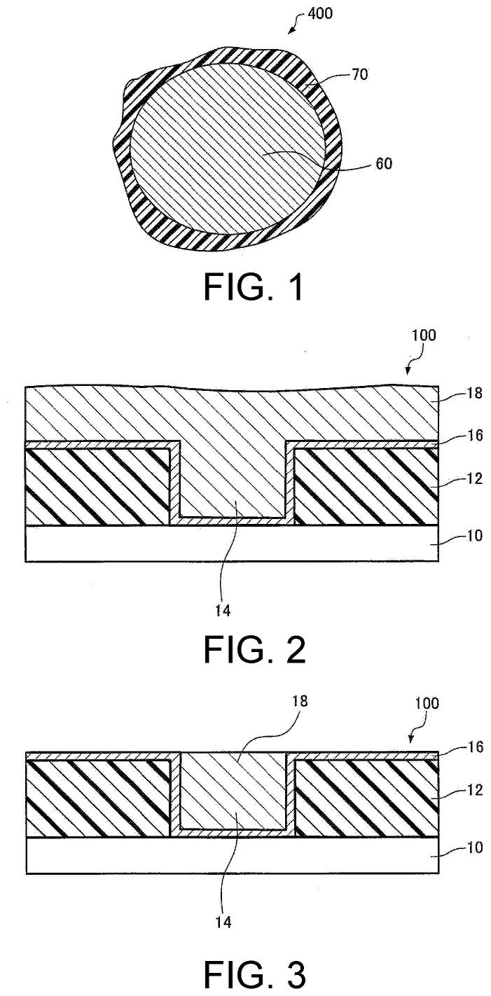

The component (A) is a particle containing alumina as a main component, and it is preferable that at least a portion of the surface of the particle be coated with a silica coating. FIG. 1 is a cross-sectional view schematically showing a particle 400 of which at least a portion of the surface is coated with a silica coating and which contains alumina. As shown in FIG. 1, in the particle 400, at least a portion of the surface of an alumina particle 60 is coated with a silica coating 70. Accordingly, the particle 400 has a core-shell shape including the alumina particle 60 as a core part and the silica coating 70 as a shell part. The entire surface or only a part of the surface of the particle 400 may be coated with the silica coating 70, but it is preferable that the entire surface be coated. When at least a portion of the surface of the particle 400 is coated with the silica coating 70, since the surface hardness of the particle 400 is appropriately alleviated, it is possible to effectively reduce the occurrence of polishing scratches such as scratches on the polished surface on which a tungsten film and a silicon oxide film coexist in some cases.

The film thickness of the silica coating 70 is preferably 1 nm or more and 10 nm or less. When the film thickness of the silica coating 70 is within the above range, it is possible to easily reduce the occurrence of polishing scratches on the polished surface without reducing the polishing rate.

When the component (A) is particles of which at least a portion of the surface is coated with a silica coating and which contains alumina, in the coating, if the number of moles of the functional group represented by General Formula (1) is M_{Sul}, and the number of moles of silicon is M_{Si}, the value of M_{Sul}/M_{Si} is preferably 0.001 or more and 0.2 or less, more preferably 0.01 or more and 0.15 or less, and particularly preferably 0.05 or more and 0.13 or less. When the value of M_{Sul}/M_{Si} in the coating is within the above range, it is possible to easily reduce the occurrence of polishing scratches on the polished surface without reducing the polishing rate.

The lower limit of the average primary particle size of the component (A) is preferably 10 nm, more preferably 50 nm, and particularly preferably 100 nm. The upper limit of the average primary particle size of the component (A) is preferably 1,000 nm, more preferably 500 nm, and particularly preferably 300 nm. When the average particle size of primary particles constituting the component (A) is within the above range, a tungsten film which is a polished surface can be polished at a practical polishing rate while minimizing the occurrence of polishing defects in some cases. The average particle size of primary particles constituting the component (A) can be confirmed by producing a sample of the component (A) by a general method and performing observation using a transmission electron microscope (TEM).

The zeta potential of the component (A) is preferably lower than −10 mV and more preferably lower than −20 mV. When the zeta potential of the component (A) in any pH range of 1 or more and 6 or less is lower than −10 mV, since a repulsive force based on the electrostatic interaction between the component (A) and the tungsten film makes it difficult for the component (A) to be excessively localized on the surface, it is possible to effectively reduce the occurrence of polishing scratches on the polished surface in some cases.

The zeta potential of the component (A) can be measured by a general method using a zeta potential measuring device using a laser Doppler method as a measurement principle. Examples of such a zeta potential measuring device include “Zeta potential analyzer” (commercially available from Brookhaven Instruments Corporation) and “ELSZ-1000ZS” (commercially available from Otsuka Electronics Co., Ltd.).

The lower limit value of the content of the component (A) with respect to a total mass of 100 mass % of the composition for chemical mechanical polishing is preferably 0.1 mass %, more preferably 0.2 mass %, and particularly preferably 0.3 mass %. The upper limit value of the content of the component (A) with respect to a total mass of 100 mass % of the composition for chemical mechanical polishing is preferably 10 mass %, more preferably 8 mass %, and particularly preferably 5 mass %. When the content of the component (A) is within the above range, it is possible to polish a tungsten film which is a wiring material at a high speed and storage stability of the composition for chemical mechanical polishing can be improved in some cases.

### 1.1.2. Method for Manufacturing Particles for Chemical Mechanical Polishing

The component (A) used in the present embodiment can be manufactured by, for example, a method including:

a process (a) in which alumina particles are dispersed in water to prepare an alumina particle aqueous dispersing liquid having a solid content concentration of 1 mass % or more and 30 mass % or less;

a process (b) in which a total amount of 1 part by mass or more and 50 parts by mass or less of a tetrafunctional alkoxysilane compound and a silanol compound having a functional group represented by the following General Formula (1) with respect to a total amount of 100 parts by mass of the alumina particles is added to the alumina particle aqueous dispersing liquid; and

a process (c) in which a silica coating is grown on the surface of the alumina particles:

—SO₃⁻M⁺ (1)

(M⁺ represents a monovalent cation).

According to such a manufacturing method, a silica coating having a uniform and appropriate film thickness can be formed on the surface of the alumina particles. Therefore, it is possible to reduce the occurrence of polishing scratches on the polished surface without reducing the polishing rate. Hereinafter, respective processes of the manufacturing method will be described in detail.

### Process (a)

The process (a) is a process in which alumina particles are dispersed in water to prepare an alumina particle aqueous dispersing liquid having a solid content concentration of 1 mass % or more and 30 mass % or less.

The average primary particle size of the alumina particles used in the process (a) is preferably 10 nm or more and 1,000 nm or less. The average primary particle size of the alumina particles can be determined by measuring, for example, the primary particle size of 100 alumina particles using a transmission electron microscope (TEM), and obtaining an average value thereof.

A method of dispersing alumina particles in water is not particularly limited, and may be performed by weighing water out in a container and gradually putting alumina particles into the container, and the entire component may be made uniform with a stirring device such as a magnetic stirrer.

In the process (a), the solid content concentration of the alumina particle aqueous dispersing liquid is adjusted to 1 mass % or more and 30 mass % or less, and preferably adjusted to 1 mass % or more and 20 mass % or less.

In addition, in the process (a), it is preferable to add ammonia water as a catalyst to the alumina particle aqueous dispersing liquid. The amount of ammonia water added is not particularly limited, and the pH of the alumina particle aqueous dispersing liquid may be adjusted to 8 to 12. In such a pH range, ammonia functions as a catalyst, and the alkoxy group of the alkoxysilane compound is hydrolyzed with water present in the surrounding environment to form a hydroxy group. On the other hand, the silanol compound originally has a hydroxy group. These hydroxy groups bond to the surface of the alumina particles by adsorption, hydrogen bonding, or dehydration bonding. In this manner, the surface of the alumina particles is coated with a silica coating. That is, “coated with a silica coating” means that a hydroxy group derived from an alkoxysilane compound and a hydroxy group of a silanol compound are bonded to the surface of the alumina particles by adsorption, hydrogen bonding, or dehydration bonding.

### Process (b)

The process (b) is a process in which a total amount of 1 part by mass or more and 50 parts by mass or less of a tetrafunctional alkoxysilane compound and a silanol compound having the functional group represented by General Formula (1) with respect to a total amount of 100 parts by mass of the alumina particles is added to the alumina particle aqueous dispersing liquid.

Examples of tetrafunctional alkoxysilane compounds include tetramethoxysilane, tetraethoxysilane, and tetrapropoxysilane. Examples of silanol compounds having the functional group represented by General Formula (1) include 3-(trihydroxysilyl)-1-propanesulfonic acid, and 2-hydroxy-3-[3-(trihydroxysilyl)propoxy]-1-propanesulfonic acid.

In the process (b), a total amount of the tetrafunctional alkoxysilane compound and the silanol compound having the functional group represented by General Formula (1) added with respect to a total amount of 100 parts by mass of the alumina particles is 1 part by mass or more and 50 parts by mass or less, and preferably 10 parts by mass or more and 35 parts by mass or less.

In addition, the mass ratio between the amount of the tetrafunctional alkoxysilane compound added and the amount of the silanol compound having the functional group represented by General Formula (1) added, based on mass, is preferably 20:1 to 1:1, more preferably 15:1 to 2:1, and particularly preferably 10:1 to 3:1.

### Process (c)

The process (c) is a process in which a coating of silica derived from the alkoxysilane compound and the silanol compound is grown on the surface of the alumina particles. Specifically, after the process (b), the alumina particle aqueous dispersing liquid to which the alkoxysilane compound and the silanol compound are added is stirred at a temperature of 90° C. or lower for 1 to 10 hours, and thus a silica coating can be grown on the surface of the alumina particles.

The upper limit of the temperature of the alumina particle aqueous dispersing liquid during stirring is preferably 90° C. On the other hand, the lower limit of the temperature of the alumina particle aqueous dispersing liquid during stirring is preferably 20° C. When a silica coating is grown within the above temperature range, the added ammonia as a catalyst does not scatter, and a silica coating having an appropriate strength can be formed on the surface of the alumina particles.

In this manner, a silica coating can be grown on the surface of the alumina particles, but it is preferable to finally cool to room temperature, add an acid, and adjust the pH to 1 to 6. When the pH is set in such a range, the interaction between the polished surface and the component (A) is induced, it is possible to further improve the polishing rate of the polished surface and effectively reduce the occurrence of polishing scratches on the polished surface in some cases.

### 1.2. Component (B)

The composition for chemical mechanical polishing according to the present embodiment contains (B) a liquid medium. Examples of the component (B) include water, a mixed medium containing water and an alcohol, and a mixed medium containing water and an organic solvent compatible with water. Among these, water or a mixed medium containing water and an alcohol is preferably used, and water is more preferably used. Water is not particularly limited, and pure water is preferable. Water may be added as the remainder of the constituent material of the composition for chemical mechanical polishing, and the content of water is not particularly limited.

### 1.3. Other Additives

The composition for chemical mechanical polishing according to the present embodiment may further contain, as necessary, additives such as an oxidant, an acidic compound, a surfactant, a water-soluble polymer, an anti-corrosive agent, and a pH adjusting agent. Hereinafter, respective additives will be described.

### Oxidant

The composition for chemical mechanical polishing according to the present embodiment may contain an oxidant. When an oxidant is contained, a metal such as tungsten is oxidized to promote a complex reaction with a polishing liquid component, and thus a fragile modified layer can be formed on the polished surface so that the polishing rate is improved in some cases.

Examples of oxidants include ammonium persulfate, potassium persulfate, hydrogen peroxide, ferric nitrate, cerium diammonium nitrate, potassium hypochlorite, ozone, potassium periodate, and peracetic acid. Among these oxidants, in consideration of oxidizing power and ease of handling, ammonium persulfate, potassium persulfate, and hydrogen peroxide are preferable, and hydrogen peroxide is more preferable. These oxidants may be used alone or two or more thereof may be used in combination.

When the composition for chemical mechanical polishing according to the present embodiment contains an oxidant, the content of the oxidant with respect to a total mass of 100 mass % of the composition for chemical mechanical polishing is preferably 0.1 to 5 mass %, more preferably 0.3 to 4 mass %, and particularly preferably 0.5 to 3 mass %.

### Acidic Compound

The composition for chemical mechanical polishing according to the present embodiment may contain an acidic compound. When an acidic compound is contained, a synergistic effect with the component (A) can be obtained, and the polishing rate of the tungsten film can be improved in some cases.

Examples of such acidic compounds include organic acids and inorganic acids. Examples of organic acids include saturated carboxylic acids such as malonic acid, citric acid, malic acid, tartaric acid, oxalic acid, lactic acid, and imminodiacetic acid; unsaturated monocarboxylic acids such as acrylic acid, methacrylic acid, crotonic acid, 2-butenoic acid, 2-methyl-3-butenoic acid, 2-hexenoic acid, and 3-methyl-2-hexenoic acid; unsaturated dcarboxylic acids such as maleic acid, fumaric acid, citraconic acid, measaconic acid, 2-pentenedioic acid, itaconic acid, allylmalonic acid, isopropylidene succinic acid, 2,4-hexadienedioic acid, and acetylenedicarboxylic acids; and aromatic carboxylic acids such as trimellitic acid, and salts thereof. Examples of inorganic acids include phosphoric acid, sulfuric acid, hydrochloric acid, nitric acid, and salts thereof. These acidic compounds may be used alone or two or more thereof may be used in combination.

When the composition for chemical mechanical polishing according to the present embodiment contains an acidic compound, the content of the acidic compound with respect to a total mass of 100 mass % of the composition for chemical mechanical polishing is preferably 0.001 to 5 mass %, more preferably 0.003 to 1 mass %, and particularly preferably 0.005 to 0.5 mass %.

### Surfactant

The composition for chemical mechanical polishing according to the present embodiment may contain a surfactant. When a surfactant is contained, it is possible to impart an appropriate viscosity to the composition for chemical mechanical polishing in some cases. It is preferable to adjust the viscosity of the composition for chemical mechanical polishing at 25° C. to 0.5 mPa·s or more and less than 10 mPa·s.

Examples of surfactants include anionic surfactants, cationic surfactants, and nonionic surfactants, but the present invention is not particularly limited thereto.

Examples of anionic surfactants include carboxylates such as fatty acid soap and alkyl ether carboxylate; sulfonates such as alkyl benzene sulfonate, alkylnaphthalenesulfonate, and a-olefin sulfonate; sulfates such as higher alcohol sulfuric ester salts, alkyl ether sulfate, and polyoxyethylene alkylphenyl ether sulfate; and fluorine-containing surfactants such as a perfluoroalkyl compound.

Examples of cationic surfactants include aliphatic amine salts and aliphatic ammonium salts.

Examples of nonionic surfactants include nonionic surfactants having triple bonds such as acetylene glycol, acetylene glycol ethylene oxide adduct, and acetylene alcohol; and polyethylene glycol type surfactants.

Among the surfactants exemplified above, alkyl benzene sulfonate is preferable, and potassium dodecylbenzene sulfonate and ammonium dodecylbenzene sulfonate are more preferable. These surfactants may be used alone or two or more thereof may be used in combination.

When the composition for chemical mechanical polishing according to the present embodiment contains a surfactant, the content of the surfactant with respect to a total mass of 100 mass % of the composition for chemical mechanical polishing is preferably 0.001 to 5 mass %, more preferably 0.003 to 3 mass %, and particularly preferably 0.005 to 1 mass %.

### Water-Soluble Polymer

The composition for chemical mechanical polishing according to the present embodiment may contain a water-soluble polymer. The water-soluble polymer has an effect in which it adsorbs on the surface of the polished surface and polishing friction is reduced. According to this effect, the occurrence of dishing on the polished surface can be significantly reduced in some cases.

Examples of water-soluble polymers include polyethyleneimine, poly(meth)acrylamide, poly N-alkyl(meth)acrylamide, poly(meth)acrylic acid, polyoxyethylene alkylamine, polyvinyl alcohol, polyvinyl alkyl ether, polyvinylpyrrolidone, hydroxyethyl cellulose, carboxymethyl cellulose, copolymers of (meth)acrylic acid and maleic acid, and polymer amine compounds such as poly(meth)acrylic amine.

The weight average molecular weight (Mw) of the water-soluble polymer is preferably 1,000 to 1,000,000, and more preferably 3,000 to 800,000. When the weight average molecular weight of the water-soluble polymer is within the above range, the polymer is likely to be adsorbed on the surface of the polished surface, and polishing friction can be further reduced in some cases. As a result, it is possible to more effectively reduce the occurrence of dishing on the polished surface in some cases. Here, the “weight average molecular weight (Mw)” in this specification is a weight average molecular weight in terms of polyethylene glycol measured by gel permeation chromatography (GPC).

When the composition for chemical mechanical polishing according to the present embodiment contains a water-soluble polymer, the content of the water-soluble polymer with respect to a total mass of 100 mass % of the composition for chemical mechanical polishing is preferably 0.005 to 0.5 mass %, and more preferably 0.01 to 0.2 mass %.

Here, the content of the water-soluble polymer also depends on the weight average molecular weight (Mw) of the water-soluble polymer, but it is preferable to adjust the viscosity of the composition for chemical mechanical polishing at 25° C. to 0.5 mPa·s or more and less than 10 mPa·s. When the viscosity of the composition for chemical mechanical polishing at 25° C. is 0.5 mPa·s or more and less than 10 mPa·s, it is easy to polish the tungsten film at a high speed and the viscosity is appropriate, and thus it is possible to stably supply the composition for chemical mechanical polishing on the polishing cloth.

### Anti-Corrosive Agent

The composition for chemical mechanical polishing according to the present embodiment may contain an anti-corrosive agent. Examples of anti-corrosive agents include benzotriazole and derivatives thereof. Here, benzotriazole derivatives are derivatives in which one or two or more hydrogen atoms of benzotriazole are replaced with, for example, a carboxyl group, a methyl group, an amino group, a hydroxy group or the like. Specific examples of benzotriazole derivatives include 4-carboxybenzotriazole, 7-carboxybenzotriazole, benzotriazole butyl ester, 1-hydroxymethylbenzotriazole, 1-hydroxybenzotriazole, and salts thereof.

When the composition for chemical mechanical polishing according to the present embodiment contains an anti-corrosive agent, the content of the anti-corrosive agent with respect to a total mass of 100 mass % of the composition for chemical mechanical polishing is preferably 1 mass % or less, and more preferably 0.001 to 0.1 mass %.

### pH Adjusting Agent

The composition for chemical mechanical polishing according to the present embodiment may further contain, as necessary, a pH adjusting agent. Examples of pH adjusting agents include nitric acid, potassium hydroxide, ethylenediamine, monoethanolamine, tetramethylammonium hydroxide (TMAH), tetraethylammonium hydroxide (TEAH), and ammonia, and one or more thereof can be used.

### 1.4. pH

The pH of the composition for chemical mechanical polishing according to the present embodiment is not particularly limited, and is preferably 1 or more and 6 or less, more preferably 2 or more and 5 or less, and particularly preferably 2 or more and 4 or less. When the pH is within the above range, the polishing rate of tungsten can be higher, while the polishing rate of the silicon oxide film can be lower in some cases. As a result, the tungsten film can be selectively polished in some cases.

Here, the pH of the composition for chemical mechanical polishing according to the present embodiment can be adjusted by, for example, appropriately increasing or decreasing the content of the acidic compound, the pH adjusting agent or the like.

In the present invention, the pH indicates a hydrogen ion index, and the value thereof can be measured under conditions of 25° C. and 1 atm using a commercially available pH meter (for example, desktop pH meter commercially available from HORIBA, Ltd.).

### 1.5. Applications

The composition for chemical mechanical polishing according to the present embodiment contains (A) particles having the functional group represented by General Formula (1) and containing alumina. Since the component (A) has the functional group represented by General Formula (1), it has a relatively large negative zeta potential in the composition for chemical mechanical polishing having a pH of 1 to 6. Therefore, in the composition for chemical mechanical polishing according to the present embodiment, since the dispersion stability is improved by a repulsive force between the components (A), it is possible to polish a tungsten film which is a wiring material at a high speed and reduce the occurrence of surface defects on the polished surface. According to the composition for chemical mechanical polishing of the present embodiment, it is possible to reduce the occurrence of polishing scratches such as scratches, particularly, on the polished surface on which a tungsten film and a silicon oxide film coexist. Therefore, the composition for chemical mechanical polishing according to the present embodiment is suitable as a polishing material for polishing a substrate containing tungsten or a substrate containing tungsten and silicon oxide among a plurality of materials constituting a semiconductor device.

### 1.6. Method of Preparing Composition for Chemical Mechanical Polishing

The composition for chemical mechanical polishing according to the present embodiment can be prepared by dissolving or dispersing the above components in a liquid medium such as water. The dissolving or dispersing method is not particularly limited, and any method may be applied as long as uniform dissolving or dispersion can be performed. In addition, the mixing order and mixing method of the above components are not particularly limited.

In addition, the composition for chemical mechanical polishing according to the present embodiment can be prepared as a concentrated type stock solution and used by being diluted in a liquid medium such as water during use.

### 2. Chemical Mechanical Polishing Method

A polishing method according to one embodiment of the present invention includes a process in which a substrate containing tungsten is polished using the above composition for chemical mechanical polishing. The substrate may further contain silicon oxide. Hereinafter, one specific example of the chemical mechanical polishing method according to the present embodiment will be described with reference to the drawings.

### 2.1. Workpiece

FIG. 2 is a cross-sectional view schematically showing a workpiece suitable for use in a chemical mechanical polishing method according to the present embodiment. A workpiece 100 is formed through the following process (1) to process (4).

(1) First, as shown in FIG. 2, a substrate 10 is prepared. The substrate 10 may be composed of, for example, a silicon substrate and a silicon oxide film formed thereon. In addition, a functional device such as a transistor (not shown) may be formed on the substrate 10. Next, a silicon oxide film 12 which is an insulating film is formed on the substrate 10 using a thermal oxidation method.

(2) Next, the silicon oxide film 12 is patterned. A via hole 14 is formed in the silicon oxide film 12 by a photolithography method using the obtained pattern as a mask.

(3) Next, a barrier metal film 16 is formed on the surface of the silicon oxide film 12 and the inner wall surface of the via hole 14 by applying sputtering or the like. Since the electrical contact between tungsten and silicon is not very good, favorable electrical contact is realized by inserting a barrier metal film. Examples of the barrier metal film 16 include titanium and/or titanium nitride.

(4) Next, a tungsten film 18 is deposited by applying a CVD method.

According to the above processes, the workpiece 100 is formed.

### 2.2. Chemical Mechanical Polishing Method

### 2.2.1. First Polishing Process

FIG. 3 is a cross-sectional view schematically showing a workpiece when a first polishing process ends. In the first polishing process, as shown in FIG. 3, the tungsten film 18 is polished until the barrier metal film 16 is exposed using the above composition for chemical mechanical polishing.

### 2.2.2. Second Polishing Process

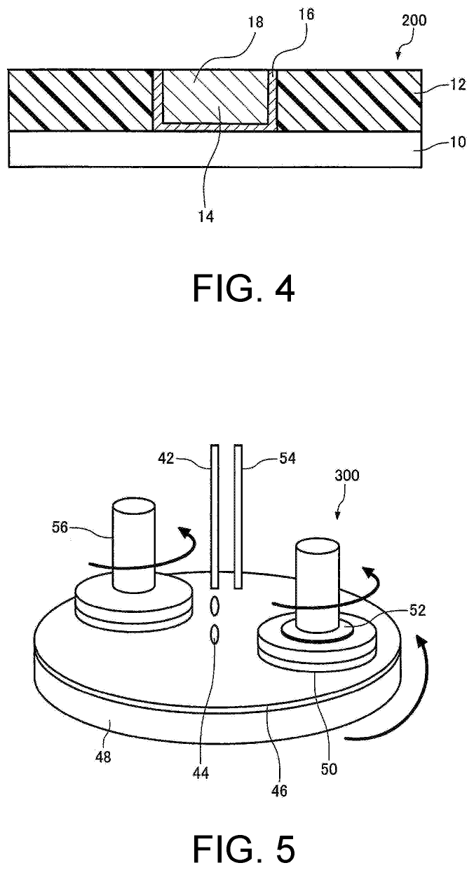

FIG. 4 is a cross-sectional view schematically showing a workpiece when a second polishing process ends. In the second polishing process, as shown in FIG. 4, the silicon oxide film 12, the barrier metal film 16, and the tungsten film 18 are polished using the above composition for chemical mechanical polishing. It is possible to manufacture a next-generation semiconductor device 200 having few surface defects on the polished surface through the second polishing process.

Here, according to the above composition for chemical mechanical polishing, it is possible to polish a tungsten film which is a wiring material at a high speed, and reduce the occurrence of surface defects on the polished surface on which a tungsten film and a silicon oxide film coexist. Therefore, the above composition for chemical mechanical polishing is suitable as a polishing material for chemical mechanical polishing of a substrate containing tungsten or a substrate containing tungsten and silicon oxide. In addition, in the first polishing process and the second polishing process of the chemical mechanical polishing method according to the present embodiment, since the composition for chemical mechanical polishing having the same composition can be used, the throughput of the production line is improved.

### 2.3. Chemical Mechanical Polishing Device

In the above first polishing process and second polishing process, for example, a polishing device 300 shown in FIG. 5 can be used. FIG. 5 is a perspective view schematically showing the polishing device 300. The above first polishing process and second polishing process are performed by supplying a slurry (composition for chemical mechanical polishing) 44 from the slurry supply nozzle 42, and bringing a carrier head 52 holding a semiconductor substrate 50 into contact with it while a turntable 48 to which a polishing cloth 46 is attached is rotated. Here, FIG. 5 also shows a water supply nozzle 54 and a dresser 56.

The polishing load of the carrier head 52 can be selected to be in a range of 10 to 980 hPa, and is preferably 30 to 490 hPa. In addition, the rotational speed of the turntable 48 and the carrier head 52 can be appropriately selected to be in a range of 10 to 400 rpm, and is preferably 30 to 150 rpm. The flow rate of the slurry (composition for chemical mechanical polishing) 44 supplied from the slurry supply nozzle 42 can be selected to be in a range of 10 to 1,000 mL/min, and is preferably 50 to 400 mL/min.

Examples of commercially available polishing devices include model “EPO-112” and “EPO-222” (commercially available from Ebara Corporation); model “LGP-510” and “LGP-552” (commercially available from Lap Master SFT); model “Mirra” and “Reflexion” (commercially available from Applied Materials, Inc.); model “POLI-400L” (commercially available from G&P TECHNOLOGY); and model “Reflexion LK” (commercially available from AMAT).

### 3. Examples

Hereinafter, the present invention will be described with reference to examples, but the present invention is not limited to these examples. Here, unless otherwise specified, “parts” and “%” in the present example are based on mass.

### 3.1. Example 1

### 3.1.1. Preparation of Sulfo Group-Modified Alumina-Containing Particle

In a 2 L flask under room temperature and atmospheric pressure, 26.70 g of tetramethyl orthosilicate (commercially available from Tama Chemicals Co., Ltd.) was mixed with 1,000 g of a water dispersing element containing alumina at a concentration of 200 g/L (commercially available from Saint-Gobain Ceramic Materials, Inc., product name “7992 alumina dispersing liquid”). Next, 28 mass % of ammonia water was added until the pH of the mixture reached 10.3. Then, the temperature was raised to 60° C. and maintained for 3 hours, and 10 g of a 30% aqueous solution was then added to 3-(trihydroxysilyl)-1-propanesulfonic acid (commercially available from FUJIFILM

Wako Pure Chemical Corporation), which was maintained at 60° C. for 2 hours. Then, 500 g of water was added, and 500 g was distilled off. Finally, 10% nitric acid was added to obtain a dispersing element containing sulfo group-modified alumina-containing particles having a pH of 4.

### 3.1.2. Evaluation of Sulfo Group-Modified Alumina-Containing Particle

For the sulfo group-modified alumina-containing particles obtained above, using a transmission electron microscope (TEM) (device model number “HITACHI H-7650” commercially available from Hitachi High-Tech Corporation), the primary particle sizes of 100 particles were measured, and an average value thereof was calculated. The results thereof are shown in Table 1 as the average primary particle size.

In addition, using a TEM scale gauge, an average value of the film thickness of the silica film formed on the particle surface was calculated from 100 particle images. The results thereof are shown in Table 1 as the coating film thickness.

### 3.1.3. Preparation of Composition for Chemical Mechanical Polishing

The dispersing element containing the sulfo group-modified alumina-containing particles prepared above was put into a polyethylene bottle having a volume of 1 L so that the content shown in Table 1 was obtained, and then, as necessary, nitric acid was added, and the pH was adjusted to a value shown in Table 1. Next, a 1% hydrogen peroxide solution was added so that the content shown in Table 1 was obtained, and water was added so that a total amount of 100 parts by mass was obtained and stirring was performed. Then, filtering was performed through a filter having a pore diameter of 0.3 μm to obtain a composition for chemical mechanical polishing.

### 3.1.4. Evaluation of Composition for Chemical Mechanical Polishing

### Measurement of Zeta Potential

The surface charge (zeta potential) of the sulfo group-modified alumina-containing particles contained in the composition for chemical mechanical polishing obtained above was measured using an ultrasonic particle size distributionzeta potential measuring device (model “DT-1200” commercially available from Dispersion Technology). The results are shown in Table 1.

### Evaluation of Polishing Rate

Using the composition for chemical mechanical polishing obtained above, a substrate having a silicon oxide film (square silicon substrate having a silicon oxide film 1,500 nm and a side length of 4 cm) and a substrate having a tungsten film (a square silicon substrate a 350 nm tungsten film and a side length of 4 cm) were used as an object to be polished and chemical mechanical polishing was performed under the following conditions using a chemical mechanical polishing device (model “Poli-400L” commercially available from G&P Technology). The evaluation criteria for the polishing rate test are as follows. The results are shown in Table 1. Here, the polishing rates of the tungsten film and the silicon oxide film were calculated using the following calculation formula.

Polishing rate (A/min)=polishing amount (A)/polishing time (minutes)

### Polishing Conditions

Polishing pad: model number “IC1000 XY-P” commercially available from Nitta Haas Inc.
Carrier head load: 129 g/cm²
Surface plate rotational speed: 100 rpm
Polishing head rotational speed: 90 rpm
Amount of composition for chemical mechanical polishing supplied: 100 mL/min

### Evaluation Criteria

“A” . . . When the polishing rate of the tungsten film was 200 Å/min or more, and the polishing rate of the tungsten film was higher than the polishing rate of the silicon oxide film.

“B” . . . When the polishing rate of the tungsten film was less than 200 Å/min, or the polishing rate of the tungsten film was lower than the polishing rate of the silicon oxide film.

### Evaluation of Defects

Respective components were put into a polyethylene container so that the composition shown in Table 1 was obtained, and adjustment with pure water was performed so that the total amount of all components was 100 parts by mass. Next, while checking with a pH meter so that the pH shown in Table 1 was obtained, adjusting with 5 mass % of a nitric acid aqueous solution was performed with stirring, and thus each composition for defect evaluation was prepared.

Using the composition for defect evaluation obtained above, for a substrate having a silicon oxide film (square silicon substrate having a silicon oxide film 1,500 nm and a side length of 4 cm), chemical mechanical polishing was performed under the following conditions using a chemical mechanical polishing device (model “Poli-400L” commercially available from G&P Technology).

### Polishing Conditions

Polishing pad: model number “IC1000 XY-P” commercially available from Nitta Haas Inc.
Carrier head load: 129 g/cm²
Surface plate rotational speed: 100 rpm
Polishing head rotational speed: 90 rpm
Amount of composition for defect evaluation supplied: 100 mL/min
For a substrate having a silicon oxide film subjected to chemical mechanical polishing using the above composition for defect evaluation, a defect area having a size of 10 μm or more was measured using a defect inspection device (model “Eclipse L200 N” commercially available from Nikon Corporation). A ratio of the measured defect area to the total substrate area (hereinafter referred to as a “defect area rate”) was calculated. The defect rate was determined by the following formula using a defect area rate of the substrate having a silicon oxide film subjected to chemical mechanical polishing using product name “7992 alumina dispersing liquid” (commercially available from Saint-Gobain Ceramic Materials, Inc.) shown in Comparative Example 1 as a reference (defect area rate=100%). Evaluation criteria for defect evaluation are as follows. The results are shown in Table 1.

Defect rate (%)=(defect area rate (%)/defect area rate (%) of 7992 alumina dispersing liquid)×100

### Evaluation Criteria

“A” . . . The defect rate defined by the above formula was 20% or less.
“B” . . . The defect rate defined by the above formula was more than 20%.

### 3.2. Example 2

Sulfo group-modified alumina-containing particles were produced and evaluated in the same manner as in Example 1 except that 15 g of a 30% aqueous solution containing 3-(trihydroxysilyl)-1-propanesulfonic acid was used. The results are shown in Table 1.

### 3.3. Example 3

Sulfo group-modified alumina-containing particles were produced and evaluated in the same manner as in Example 1 except that 13.35 g of tetramethyl orthosilicate and 5 g of a 30% aqueous solution containing 3-(trihydroxysilyl)-1-propanesulfonic acid were used. The results are shown in Table 1.

### 3.4. Example 4

Sulfo group-modified alumina-containing particles were produced and evaluated in the same manner as in Example 1 except that 40.05 g of tetramethyl orthosilicate and 15 g of a 30% aqueous solution containing 3-(trihydroxysilyl)-1-propanesulfonic acid were used. The results are shown in Table 1.

### 3.5. Example 5

Sulfo group-modified alumina-containing particles were produced and evaluated in the same manner as in Example 1 except that the pH of the composition for chemical mechanical polishing was changed to 6. The results are shown in Table 1.

### 3.6. Comparative Example 1

A composition for chemical mechanical polishing was produced and evaluated in the same manner as in Example 1 except that a water dispersing element containing alumina at a concentration of 200 g/L (product name “7992 alumina dispersing liquid” commercially available from Saint-Gobain Ceramic Materials, Inc.) was directly used as abrasive grains of the composition for chemical mechanical polishing. The results are shown in Table 1.

### 3.7. Evaluation Results

The following Table 1 shows compositions and evaluation results of compositions for chemical mechanical polishing of examples and comparative examples.

TABLE 1

| | | | Example | Example | Example | Example | Example | Comparative |
|---|---|---|---|---|---|---|---|---|
| | | | 1 | 2 | 3 | 4 | 5 | Example 1 |
| Composition | Particles for | Coating film | 8 | 8 | 5 | 10 | 8 | — |
| for chemical | chemical | thickness (nm) | | | | | | |
| mechanical | mechanical | M_{Sul}(mol) | 0.015 | 0.022 | 0.008 | 0.022 | 0.015 | — |
| polishing | polishing | M_{Si}(mol) | 0.175 | 0.175 | 0.088 | 0.300 | 0.175 | — |
| | | M_{Sul}/M_{Si} | 0.086 | 0.126 | 0.091 | 0.073 | 0.086 | — |
| | | Average primary | 116 | 116 | 116 | 120 | 116 | 100 |
| | | particle size (nm) | | | | | | |
| | | Zeta potential | −20 | −30 | −20 | −35 | −20 | 50 |
| | | (mV) | | | | | | |
| | | Content (mass %) | 1.0 | 1.0 | 1.0 | 1.0 | 1.0 | 1.0 |
| | Oxidant | Hydrogen | 1.0 | 1.0 | 1.0 | 1.0 | 1.0 | 1.0 |
| | | peroxide | | | | | | |
| | | (mass %) | | | | | | |
| | pH | | 2.5 | 2.5 | 2.5 | 2.5 | 6.0 | 2.5 |
| Evaluation | Polishing | TEOS polishing | 48 | 45 | 60 | 39 | 50 | 91 |
| item | rate | rate (Å/min) | | | | | | |
| | | W polishing rate | 250 | 235 | 300 | 230 | 250 | 402 |
| | | (Å/min) | | | | | | |
| | | Evaluation result | A | A | A | A | A | A |
| | Defect | Defect rate (%) | 0.2 | 0.8 | 2.0 | 0.3 | 10.0 | 100.0 |
| | evaluation | Evaluation result | A | A | A | A | A | B |

According to the evaluation results of the above Table 1, it was found that, in the compositions for chemical mechanical polishing of Examples 1 to 5, since the sulfo group-modified alumina-containing particles having a zeta potential of −35 mV to −20 mV were used, the stability in the composition for chemical mechanical polishing was excellent. In addition, it was found that, according to the compositions for chemical mechanical polishing of Examples 1 to 5, it was possible to polish a tungsten film which is a wiring material at a high speed. In addition, since at least a portion of the surface of the sulfo group-modified alumina-containing particles contained in the compositions for chemical mechanical polishing of Examples 1 to 5 was coated with a silica coating, the surface hardness was appropriately alleviated. Therefore, it was found that the defect rate of the substrate after polishing could be significantly reduced.

On the other hand, when the composition for chemical mechanical polishing of Comparative Example 1 containing alumina-containing particles having no sulfo group and not coated with a silica coating was used, the defect rate of the substrate after polishing was very high.

The present invention is not limited to the above embodiments, and various modifications can be made. For example, the present invention includes any configurations that are substantially the same (for example, configurations with the same functions, methods and results, or configurations with the same purposes and effects) as the configurations described in the embodiments. In addition, the present invention includes configurations in which non-essential parts of the configurations described in the embodiments are replaced. In addition, the present invention includes configurations having the same operational effects as the configurations described in the embodiments or configurations that can achieve the same purposes. In addition, the present invention includes configurations in which a known technique is added to the configurations described in the embodiments.

### REFERENCE SIGNS LIST

10 Substrate
12 Silicon oxide film
14 Via hole
16 Barrier metal film
18 Tungsten film
42 Slurry supply nozzle
44 Composition for chemical mechanical polishing (slurry)
46 Polishing cloth
48 Turntable
50 Semiconductor substrate
52 Carrier head
54 Water supply nozzle
56 Dresser
60 Alumina particle
70 Silica coating
100 Workpiece
200 Semiconductor device
300 Chemical mechanical polishing device
400 Alumina-containing particles coated with silica coating

1. A composition for chemical mechanical polishing, comprising:
(A) particles having a functional group represented by the following General Formula (1) and containing alumina; and
(B) a liquid medium:
—SO₃⁻M⁺ (1)
(M⁺ represents a monovalent cation).

2. The composition for chemical mechanical polishing according to claim 1,
wherein the component (A) is particles having a surface to which the functional group represented by General Formula (1) is fixed via a covalent bond and containing alumina.

3. The composition for chemical mechanical polishing according to claim 1,
wherein at least a portion of the surface of the particles is coated with a silica coating, and
wherein, in the coating, if the number of moles of the functional group represented by General Formula (1) is M_{Sul}, and the number of moles of silicon is M_{Si}, the value of M_{Sul}/M_{Si} is 0.001 or more and 0.2 or less.

4. The composition for chemical mechanical polishing according to claim 3,
wherein the film thickness of the silica coating is 1 nm or more and 10 nm or less.

5. The composition for chemical mechanical polishing according to claim 1,
wherein the average primary particle size of the particles is 50 nm or more and 300 nm or less.

6. The composition for chemical mechanical polishing according to claim 1,
wherein a zeta potential of the component (A) measured using a laser Doppler method is lower than −10 mV.

7. The composition for chemical mechanical polishing according to claim 1,
wherein the pH is 1 or more and 6 or less.

8. The composition for chemical mechanical polishing according to claim 1, which is for polishing a substrate containing tungsten.

9. A chemical mechanical polishing method, comprising
a process in which a substrate containing tungsten is polished using the composition for chemical mechanical polishing according to claim 1.

10. The chemical mechanical polishing method according to claim 9,
wherein the substrate further contains silicon oxide.

11. The chemical mechanical polishing method according to claim 9,
wherein the pH of the composition for chemical mechanical polishing is 1 or more and 6 or less.

12. A method for manufacturing particles for chemical mechanical polishing, comprising:
a process (a) in which alumina particles are dispersed in water to prepare an alumina particle aqueous dispersing liquid having a solid content concentration of 1 mass % or more and 30 mass % or less;
a process (b) in which a total amount of 1 part by mass or more and 50 parts by mass or less of a tetrafunctional alkoxysilane compound and a silanol compound having a functional group represented by the following General Formula (1) with respect to a total amount of 100 parts by mass of the alumina particles is added to the alumina particle aqueous dispersing liquid; and
a process (c) in which a silica coating is grown on the surface of the alumina particles:
—SO₃⁻M⁺ (1)
(M⁺ represents a monovalent cation).

13. The method for manufacturing particles for chemical mechanical polishing according to claim 12,
wherein the process (c) is performed at a temperature of 90° C. or lower.

14. The method for manufacturing particles for chemical mechanical polishing according to claim 12,
wherein the process (a) further comprises adding ammonia water to the alumina particle aqueous dispersing liquid.

15. The composition for chemical mechanical polishing according to claim 2,
wherein at least a portion of the surface of the particles is coated with a silica coating, and
wherein, in the coating, if the number of moles of the functional group represented by General Formula (1) is M_{Sul}, and the number of moles of silicon is M_{Si}, the value of M_{Sul}/M_{Si} is 0.001 or more and 0.2 or less.

16. The composition for chemical mechanical polishing according to claim 2,
wherein the average primary particle size of the particles is 50 nm or more and 300 nm or less.

17. The composition for chemical mechanical polishing according to claim 2,
wherein a zeta potential of the component (A) measured using a laser Doppler method is lower than −10 mV.

18. The composition for chemical mechanical polishing according to claim 2,
wherein the pH is 1 or more and 6 or less.

19. The chemical mechanical polishing method according to claim 10,
wherein the pH of the composition for chemical mechanical polishing is 1 or more and 6 or less.

20. The method for manufacturing particles for chemical mechanical polishing according to claim 13,
wherein the process (a) further comprises adding ammonia water to the alumina particle aqueous dispersing liquid.
